(19) United States
(12) Patent Application Publication
(10) Pub. No.: US 2026/0068190 A1
(43) Pub. Date: Mar. 5, 2026

(54) SEMICONDUCTOR DEVICE AND METHOD OF FORMING THE SAME

(71) Applicant: United Microelectronics Corp., Hsinchu (TW)

(72) Inventors: Yueh Chang Lin, Tainan City (TW); Shin-Hung Li, Nantou County (TW); Shan-Shi Huang, Hsinchu City (TW); Ming-Hua Tsai, Tainan City (TW); Chiu-Te Lee, Hsinchu County (TW)

(73) Assignee: United Microelectronics Corp., Hsinchu (TW)

(21) Appl. No.: 18/892,567

(22) Filed: Sep. 23, 2024

(30) Foreign Application Priority Data
Sep. 5, 2024 (TW) 113133642

(51) Int. Cl. H10D 1/47

(52) U.S. Cl. CPC H10D 1/47

(57) ABSTRACT

A semiconductor device and a method of forming the same are provided. The semiconductor device includes: a semiconductor substrate; an isolation region that is located in the semiconductor substrate; a dummy metal gate that is located on the isolation region that the dummy metal gate is divided into multiple independent discrete segments along a first axis of the dummy metal gate and a second axis of the dummy metal gate, and the first axis and the second axis are perpendicular to each other; a dielectric layer that covers the dummy metal gate; a high resistance impedance layer that is located on the dielectric layer; and a capping layer that is located on the high resistance impedance layer.

### CROSS-REFERENCE TO RELATED APPLICATION

This application claims the priority benefit of Taiwan application serial no. 113133642, filed on Sep. 5, 2024. The entirety of the above-mentioned patent application is hereby incorporated by reference herein and made a part of this specification.

### BACKGROUND

### Technical Field

The disclosure relates to a semiconductor device, and in particular to a semiconductor device and a method of forming the same.

### Description of Related Art

As dimensions of semiconductor devices continue to shrink, metal has become another choice for gate materials. However, during a planarization processing, such as chemical mechanical planarization (CMP), it is easy for a problem of dishing to occur on an isolation region where no gates are present. The process yield and the electrical performance of the device are affected.

Therefore, in a layout schematic view of a semiconductor device A as shown in FIG. 1A and in a partial cross-sectional schematic view of the semiconductor device A as shown in FIG. 1B, a bulk dummy metal gate DG is often also formed above an isolation region 110 to avoid the problem of dishing due to lack of metal gates on the isolation region 110 during CMP processing.

However, there is often a phenomenon of metal precipitation ME on the large-area dummy metal gate DG. Protrusions of stacked layers that are subsequently formed are caused. For example, as shown in FIG. 1B, metal precipitation ME on the dummy metal gate DG causes protrusions of an upper dielectric layer 160, a high resistance impedance layer 180 and a capping layer 190 that are subsequently formed. Due to limited heights of contact plugs CP, the distance between the high resistance impedance layer 180 and a first metal M1 is too close and leads to problems, such as burnt out or poor results in time dependent dielectric layer breakdown (TDDB).

### SUMMARY

Based on the foregoing problems, the disclosure proposes a semiconductor device and a method of forming the same. While a problem of metal precipitation is effectively avoided, a problem of dishing after CMP grinding may also be avoided.

An embodiment of the disclosure provides a semiconductor device that includes: a semiconductor substrate; an isolation region that is located in the semiconductor substrate; a dummy metal gate that is located on the isolation region that the dummy metal gate is divided into multiple independent discrete segments along a first axis of the dummy metal gate and a second axis of the dummy metal gate, and the first axis and the second axis are perpendicular to each other; a dielectric layer that covers the dummy metal gate; a high resistance impedance layer that is located on the dielectric layer; and a capping layer that is located on the high resistance impedance layer.

An embodiment of the disclosure provides a method of forming a semiconductor device that includes: a semiconductor substrate is provided; an isolation region is embedded in the semiconductor substrate; a dummy metal gate is formed on the isolation region that the dummy metal gate is divided into multiple independent discrete segments along a first axis of the dummy metal gate and a second axis of the dummy metal gate, and the first axis and the second axis are perpendicular to each other; a dielectric layer is formed to cover the dummy metal gate; a high resistance impedance layer is formed on the dielectric layer; and a capping layer is formed on the high resistance impedance layer.

In some embodiments, the semiconductor device is a high-voltage device, a medium-voltage device, a low-voltage device or a combination thereof.

In some embodiments, the isolation region includes a shallow trench isolation.

In some embodiments, a gate oxide layer is further included between the isolation region and the dummy metal gate.

In some embodiments, the dummy metal gate is a rectangle.

In some embodiments, the dummy metal gate is a hollow rectangle.

In some embodiments, each of the multiple independent discrete segments is coplanar.

In some embodiments, each of the multiple independent discrete segments is a rectangle.

In some embodiments, each of the multiple independent discrete segments is non-rectangular.

In some embodiments, dimensions of the multiple independent discrete segments are 0.01 microns to 10 microns.

Based on the above, the disclosure provides a semiconductor device and a method of forming the same. By dividing the dummy metal gate into the multiple independent discrete segments, and even hollowing out the middle of the dummy metal gate, the entire area of the dummy metal gate is reduced. In addition, the area of every independent discrete segment that has been divided is significantly reduced compared to the area of the original large-area bulk dummy metal gate. Therefore, the probability of metal precipitation is also significantly reduced. In addition, since the dummy metal gate still exists in the region, a phenomenon of dishing after CMP may also be prevented.

That is to say, based on the layout design of the special dummy metal gate of the disclosure, a problem of metal precipitation of the dummy metal gate and a phenomenon of dishing after CMP may be solved at the same time.

In addition, the semiconductor device and the method of forming the same taught in the disclosure may be applied in a high-voltage device, a medium-voltage device, a low-voltage device or a combination thereof, so it is a disclosure that can be widely applied.

In order to make the above-mentioned features and advantages of the disclosure more obvious and easy to understand, embodiments are given below and described in detail with reference to the accompanying drawings.

### BRIEF DESCRIPTION OF THE DRAWINGS

FIG. 1A is a layout schematic view of a conventional semiconductor device A.

FIG. 1B is a partial cross-sectional schematic view of the semiconductor device A viewed along section line aa′ in FIG. 1A.

FIG. 2A is a layout schematic view of a semiconductor device B according to an example of the disclosure.

FIG. 2B is a partial cross-sectional schematic view of the semiconductor device B viewed along section line bb′ in FIG. 2A.

FIG. 3A is a layout schematic view of a semiconductor device C according to an embodiment of the disclosure.

FIG. 3B is a partial enlarged view of a dotted box c of the semiconductor device C in FIG. 3A.

FIG. 4A to FIG. 4C are cross-sectional schematic views of a method of forming the semiconductor device C viewed along section line cc′ in FIG. 3A and FIG. 3B.

FIG. 5A is a layout schematic view of a semiconductor device D according to another embodiment of the disclosure.

FIG. 5B is a partial enlarged view of a dotted box d of the semiconductor device D in FIG. 5A.

FIG. 6A to FIG. 6C are cross-sectional schematic views of a method of forming the semiconductor device D viewed along section line dd′ in FIG. 5A and FIG. 5B.

### DESCRIPTION OF THE EMBODIMENTS

The embodiments are described in detail below with reference to the accompanying drawings, but the embodiments are not intended to limit the scope of the disclosure. In addition, the drawings are for illustrative purposes only and are not drawn to the original dimensions. For ease of understanding, the same components in the following description are denoted by the same reference symbols and will not be described again in the following paragraphs.

Regarding the terms, such as “comprise,” “include,” and “have,” used herein, they are all open terms, that is, “including but not limited to.”

In addition, the directional terms mentioned in the specification, such as “up” and “down,” are only used to refer to the direction of the drawings and are not used to limit the disclosure. Therefore, it should be understood that “up” and “down” may be used interchangeably and that when an element, such as a layer or film, is disposed “on” another element, the element may be directly disposed on the other element, or there may be intervening elements present. On the other hand, when an element is referred to be “directly” disposed “on” another element, there are no intervening elements between them.

As used herein, “about,” “approximately” or “substantially” includes the values as mentioned and the average values within the range of acceptable deviations that can be determined by those of ordinary skill in the art. Consider to the specific amount of errors related to the measurements (that is, the limitations of the measurement system), the meaning of “about” may be, for example, referred to a value within one or more standard deviations of the value, or within ±30%, ±20%, ±10%, ±5%. Furthermore, the “about,” “approximately” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

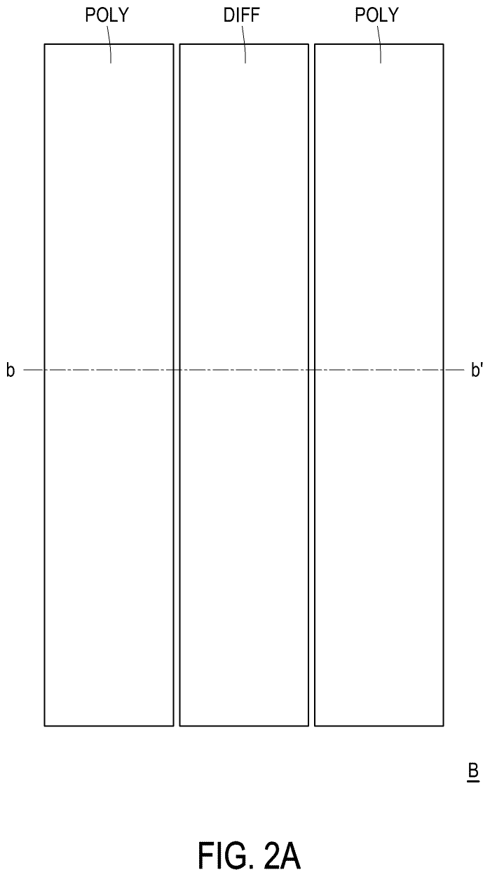

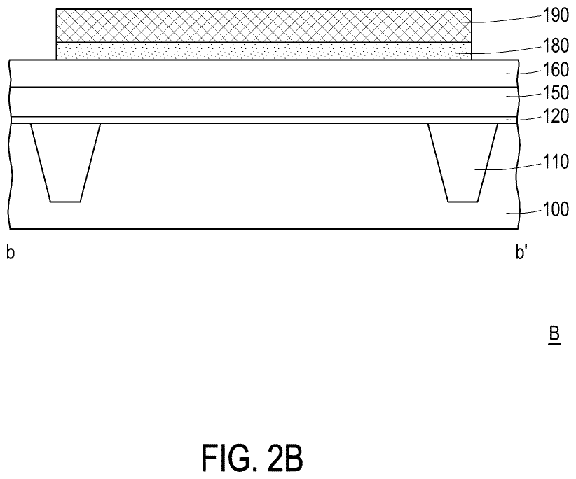

First, please refer to FIG. 2A and FIG. 2B. FIG. 2A is a layout schematic view of a semiconductor device B according to an example of the disclosure. FIG. 2B is a partial cross-sectional schematic view of the semiconductor device B viewed along section line bb′ in FIG. 2A.

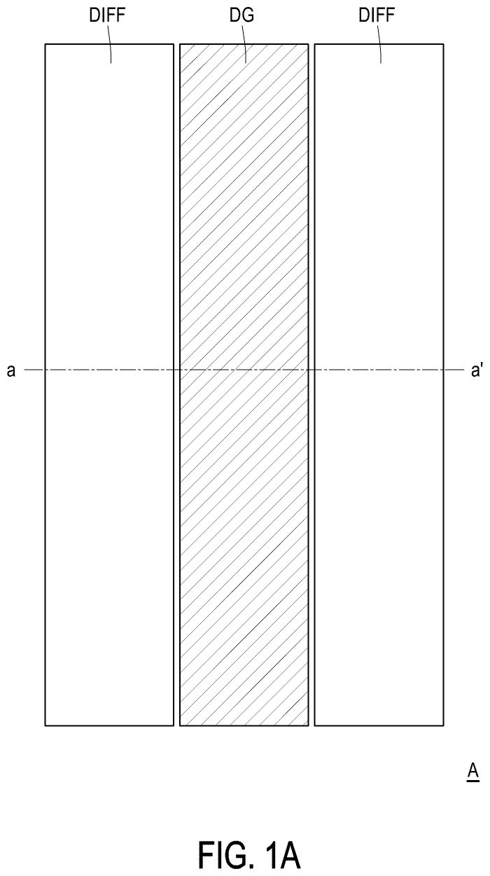

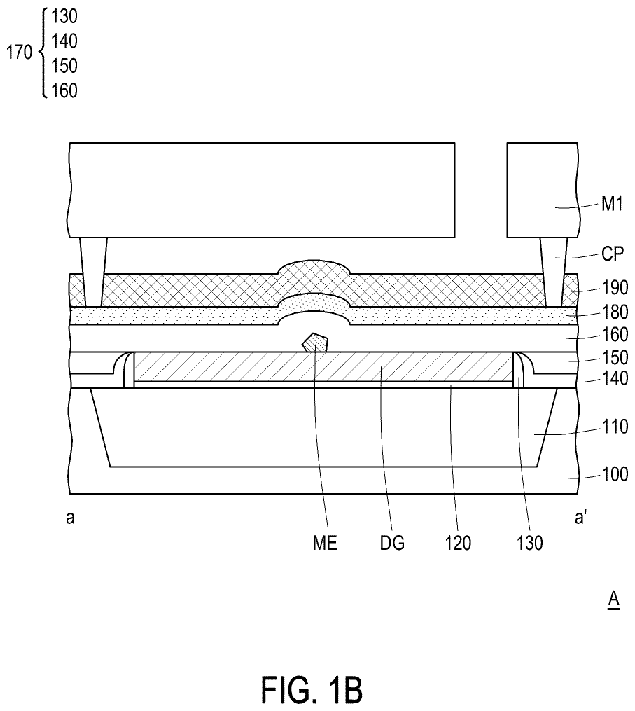

In order to solve the foregoing problem of metal precipitation, as shown in FIG. 2A and FIG. 2B, a dummy metal gate DG shown in FIG. 1A to FIG. 1B is not formed and is replaced by polycrystalline layers POLY and a diffusion layer DIFF in FIG. 2A relative to the diffusion layers DIFF and the dummy metal gate DG in FIG. 1A. In this way, as shown in FIG. 2B, a gate oxide layer 120, an interlayer dielectric layer 150, an upper dielectric layer 160, a high resistance impedance layer 180, a capping layer 190, etc. are sequentially formed on a semiconductor substrate 100 with an isolation region 110 embedded inside. In this way, since the large-area dummy metal gate DG that causes a phenomenon of metal precipitation ME no longer exists, metal precipitation ME shown in FIG. 1B does not occur, so that problems, such as burnout or poor results in TDDB, due to the distance between the high resistance impedance layer 180 and the first metal M1 being too close may be solved.

However, since the structure of the semiconductor device B shown in FIG. 2A to FIG. 2C is not provided with the dummy metal gate DG, a problem of dishing is generated on a polished surface during a global planarization processing, such as CMP.

Therefore, the disclosure proposes a divided dummy metal gate. While a problem of metal precipitation is effectively avoided, a problem of dishing after CMP grinding may also be avoided.

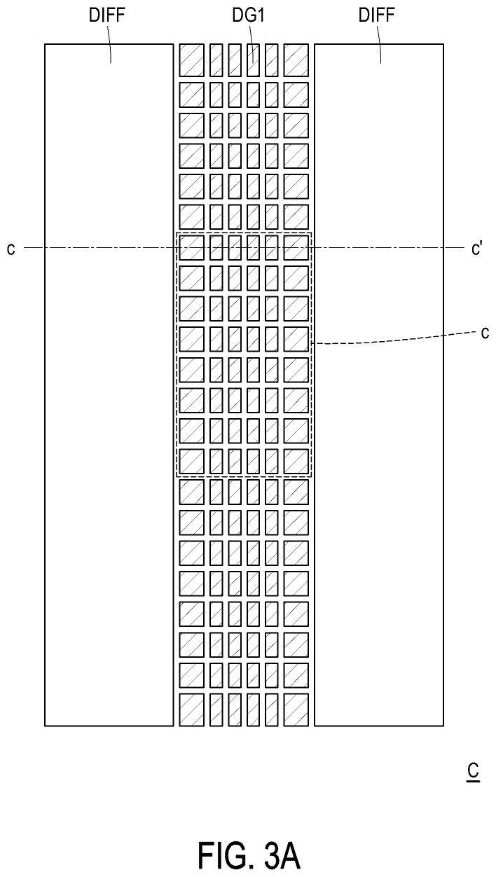

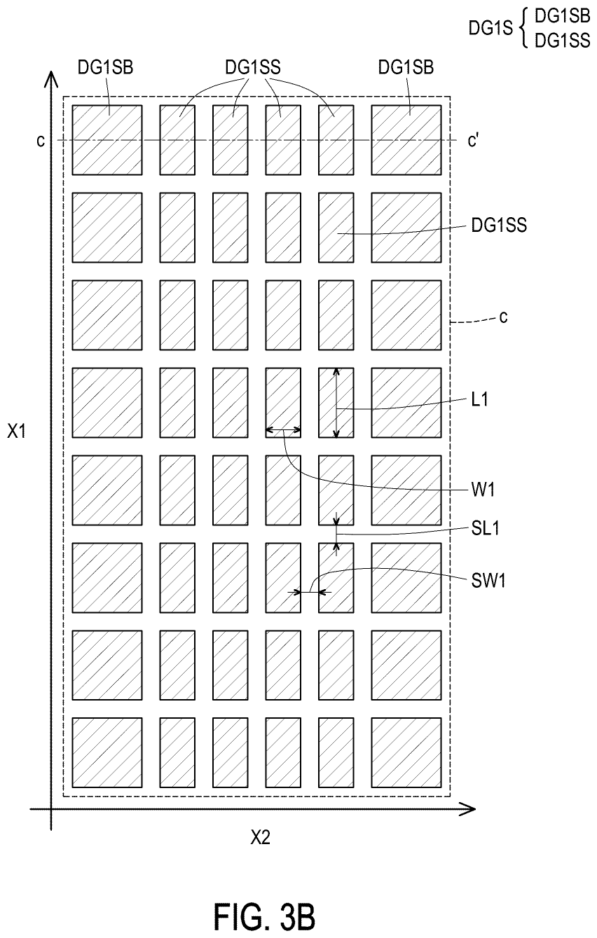

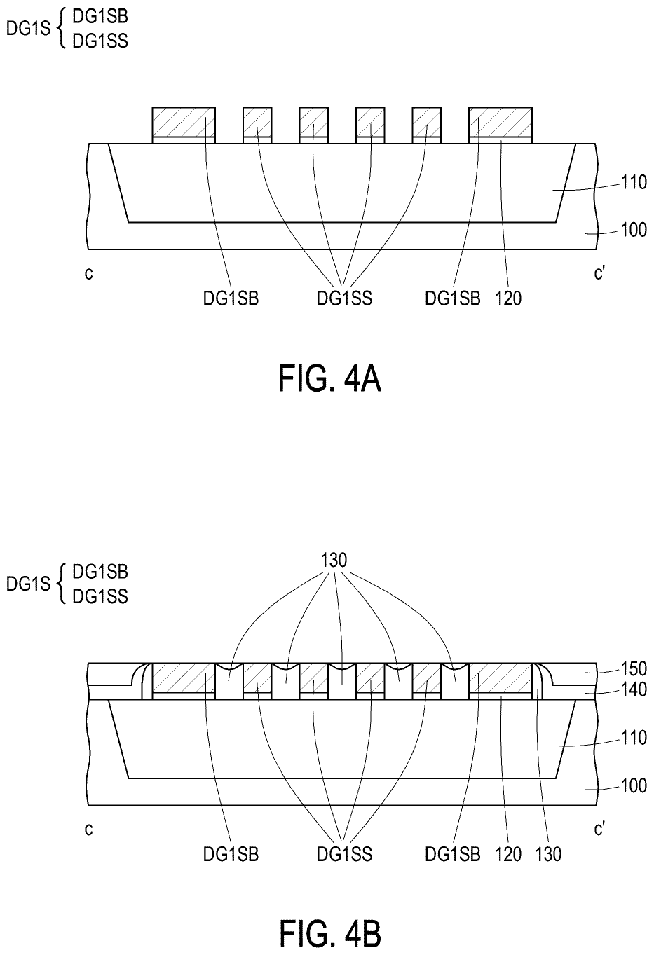

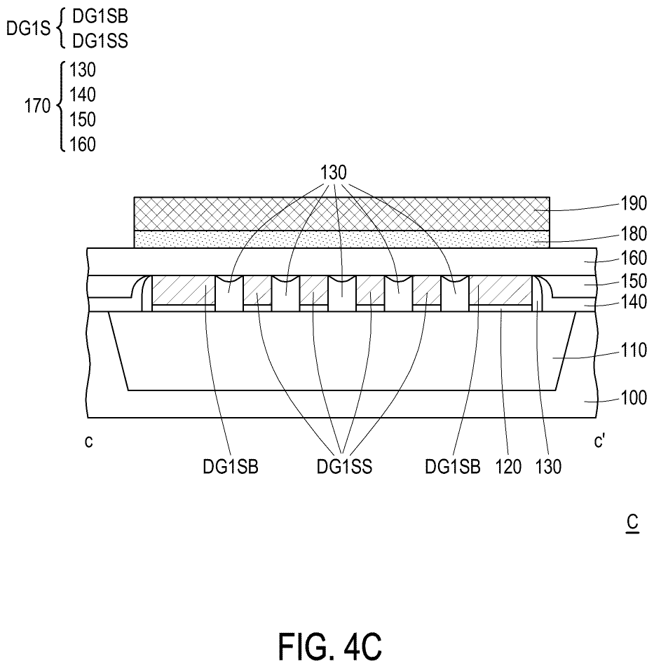

According to an embodiment provided by the disclosure, please refer to FIG. 3A, FIG. 3B and FIG. 4A to FIG. 4C at the same time. FIG. 3A is a layout schematic view of a semiconductor device C according to an embodiment of the disclosure. FIG. 3B is a partial enlarged view of a dotted box c of the semiconductor device C in FIG. 3A. FIG. 4A to FIG. 4C are cross-sectional schematic views of a method of forming the semiconductor device C viewed along section line cc′ of FIG. 3A and FIG. 3B.

First, as shown in FIG. 3A and FIG. 4A, the semiconductor device C and the method of forming the same according to the embodiment include: a semiconductor substrate 100 is provided; an isolation region 110 is embedded in the semiconductor substrate 100; a dummy metal gate DG1 is formed between diffusion regions DIFF on the isolation region 110 that the dummy metal gate DG1 is divided into multiple independent discrete segments DG1S along a first axis X1 of the dummy metal gate DG1 and an second axis X2 of the dummy metal gate DG1, and the first axis X1 and the second axis X2 are perpendicular to each other as shown in FIG. 3A, FIG. 3B and FIG. 4A.

The foregoing isolation region 110 may include various isolation components, such as a shallow trench isolation (STI).

The semiconductor device C further includes a gate oxide layer 120 between the isolation region 110 and the dummy metal gate DG1. As shown in FIG. 4A, the gate oxide layer 120 is located between the isolation region 110 and multiple large independent discrete segments DG1SB and between the isolation region 110 and multiple small independent discrete segments DG1SS.

In some embodiments, the gate oxide layer 120 may include silicon dioxide, rare earth metal oxides, lanthanide metal oxides, etc., such as hafnium oxide (HfO₂) , hafnium silicon oxide (HfSiO₄) , hafnium silicon oxynitride (HfSiO₄) , aluminum oxide (Al₂O₃) , lanthanum oxide (La₂O₃) , lanthanum aluminum oxide (LaAlO), tantalum oxide, Ta₂O₅), zirconium oxide (ZrO₂), zirconium silicon oxide (ZrSiO₄) , hafnium zirconium oxide (HfZrO), yttrium oxide (Yb₂O₃) , yttrium silicon oxide (YbSiO), zirconium aluminate (ZrAlO), hafnium aluminate (HfAlO), titanium oxide (TiO₂) , zirconium oxynitride (ZrON), hafnium oxynitride (HfON), zirconium silicon oxynitride (ZrSiON), hafnium silicon oxynitride (HfSiON), strontium bismuth tantalate (SrBi₂Ta₂O₉, SBT), etc., but it is not limited thereto.

The dummy metal gate DG1 may include metal, metal alloy, and/or metal silicide. For example, it may include aluminum (Al), titanium (Ti), tantalum (Ta), tungsten (W), niobium (Nb), molybdenum (Mo), copper (Cu), titanium nitride (TiN), titanium carbide (TiC), tantalum nitride (TaN), titanium tungsten (Ti/W) or other composite metal layer materials such as titanium and titanium nitride (Ti/TiN), but it is not limited thereto.

In some embodiments, the dummy metal gate DG1 is a rectangle, as shown in FIG. 3A. In the rectangular dummy metal gate DG1, every independent discrete segment DG1S divided by the first axis X1 of the dummy metal gate DG1 and the second axis X2 of the dummy metal gate DG1 may be chosen as needed to be divided into appearances such as same dimensions and same shapes, different dimensions and same shapes, same dimensions and different shapes, or different dimensions and different shapes. Each of the multiple independent discrete segments DG1S may be a rectangle, such as strip, square; alternatively, each of the multiple independent discrete segments DG1S may be non-rectangular, for example, polygons such as circle, triangle, trapezoid, pentagon and hexagon, or various layout shapes generated by any optical operation, but it is not limited thereto.

For example, as shown in FIG. 3A and FIG. 3B, each of the multiple independent discrete segments DG1S is a rectangle, and squares and scalene rectangles of different dimensions are included. More specifically, as shown in FIG. 3A and FIG. 3B, the multiple independent discrete segments DG1S include the multiple large independent discrete segments DG1SB adjacent to the diffusion regions DIFF, and the multiple small independent discrete segments DG1SS located inside the multiple independent discrete segments DG1S, but the actual application is not limited thereto. Various suitable cutting types may be designed as needed.

Based on the above, taking the multiple small independent discrete segments DG1SS located inside the multiple independent discrete segments DG1S as an example, as shown in FIG. 3B, every small independent discrete segment DG1SS has a length L1 along the first axis X1, and every small independent discrete segment DG1SS has a width W1 along the second axis X2. In addition, every small independent discrete segment DG1SS has a pitch SL1 along the first axis X1, and every small independent discrete segment DG1SS has a pitch SW1 along the second axis X2.

Since the original large-area bulk dummy metal gate DG shown in FIG. 1A has been divided into the multiple independent discrete segments DG1S that include the multiple small independent discrete segments DG1SS and the multiple large independent discrete segments DG1SB divided along the first axis X1 of the dummy metal gate DG1 and the second axis X2 of the dummy metal gate DG1 shown in FIG. 3A, with the presence of the pitch SL1 and the pitch SW1, the area of every small independent discrete segment DG1SS and the area of every large independent discrete segment DG1SB have become much smaller than the area of the original bulk dummy metal gate DG. Therefore, the probability of metal precipitation from the multiple small independent discrete segments DG1SS and the multiple large independent discrete segments DG1SB is also relatively much smaller. In addition, there is still support from the dummy metal gate DG1 in the region that may also avoid the occurrence of a phenomenon of dishing after CMP; that is to say, based on the layout design of the special dummy metal gate of the disclosure, a problem of metal precipitation of the dummy metal gate and a phenomenon of dishing after CMP may be solved at the same time.

The dimension of each of the foregoing independent discrete segments DG1S may be about 0.01 microns to about 10 microns, more preferably about 0.05 microns to about 5 microns, and most preferably about 0.1 microns to about 3 microns. The dimension refers to values such as lengths, widths, and diameters. That is to say, as shown in FIG. 3B, the width W1 of every small independent discrete segment DG1SS may be about 0.01 microns to about 10 microns, more preferably about 0.05 microns to about 5 microns, and most preferably about 0.1 microns to about 3 microns. The length L1 of every small independent discrete segment DG1SS may be about 0.01 microns to about 10 microns, more preferably about 0.05 microns to about 5 microns, and most preferably about 0.1 microns to about 3 microns. If the dimension of every independent discrete segment DG1S is too small, it may cause a burden on processes, such as photolithography, and there may still be a phenomenon of dishing after CMP due to insufficient bearing capacity. However, if the dimension of every independent discrete segment DG1S is too large, the metal of the dummy metal gate DG1 is still very likely to be precipitated.

The dimension range of every independent discrete segment DG1S taught above is sufficient to be applied in a high-voltage device, a medium-voltage device, a low-voltage device or a combination thereof, so the disclosure is a disclosure that can be widely applied.

In addition, the pitch SL1 and the pitch SW1 may be about 0.329 microns to about 0.116 microns, more preferably about 0.154 microns to about 0.116 microns, and most preferably about 0.120 microns to about 0.116 microns.

Please refer to FIG. 4B and FIG. 4C. A dielectric layer 170 may be formed to cover the dummy metal gate DG1. The dielectric layer 170 may include a sidewall 130, a contact etching stop layer (CETL) 140, an interlayer dielectric layer 150 and an upper dielectric layer 160, but it is not limited thereto.

For example, the sidewalls 130 and the contact etching stop layer 140 may be conformally formed on the sidewalls of every small independent discrete segment DG1SS and every large independent discrete segment DG1SB and on the semiconductor substrate 100 and the isolation region 110. Next, the interlayer dielectric layer 150 is formed on the contact etching stop layer 140. The side walls 130, the contact etching stop layer 140, the interlayer dielectric layer 150 on every small independent discrete segment DG1SS and every large independent discrete segment DG1SB are removed by a global planarization method, such as CMP, to allow each of the multiple independent discrete segments DG1S to be coplanar, as shown in FIG. 4B.

In some embodiments, the sidewalls 130 may include materials, such as silicon oxide, high temperature oxide (HTO), silicon nitride, silicon nitride (HCD-SiN) formed by using hexachlorodisilane (Si₂Cl₆) , silicon oxide-silicon nitride-silicon oxide (ONO), and nitrogen-doped silicon carbide (SiCN), but it is not limited thereto.

In some embodiments, the contact etching stop layer 140 may include materials, such as nitride, for example, silicon nitride, but it is not limited thereto.

In some embodiments, the interlayer dielectric layer 150 may include materials, such as phosphosilicate glass (PSG), borosilicate glass (BSG), borophosphosilicate glass (BPSG) or low dielectric constant materials, but it is not limited thereto.

Please refer to FIG. 4C. Next, the upper dielectric layer 160 is formed on the multiple independent discrete segments DG1S and the interlayer dielectric layer 150. Then, a high resistance impedance layer 180 is formed on the dielectric layer 170, and a capping layer 190 is formed on the high resistance impedance layer 180.

In some embodiments, the upper dielectric layer 160 may be formed of various dielectric materials, such as tetraethoxysilane (TEOS), but it is not limited thereto.

In some embodiments, the high resistance impedance layer 180 may include TiN or TaN, but it is not limited thereto.

In some embodiments, the capping layer 190 may include silicon nitride, but it is not limited thereto.

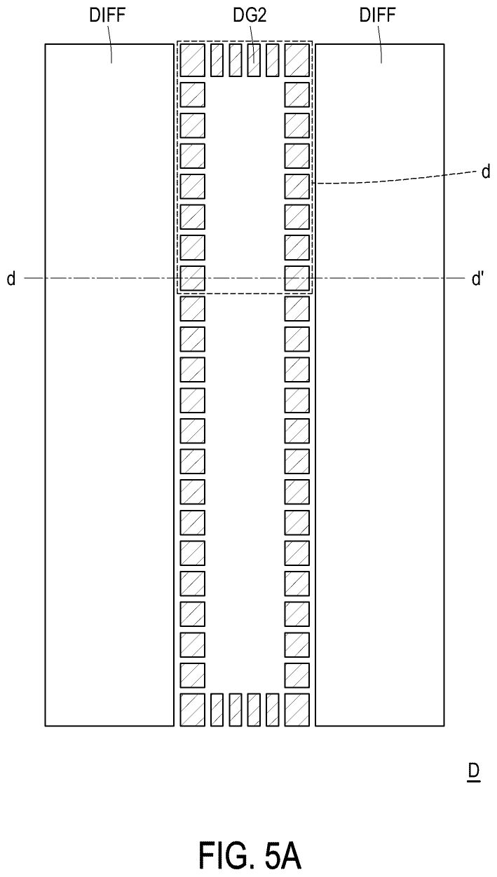

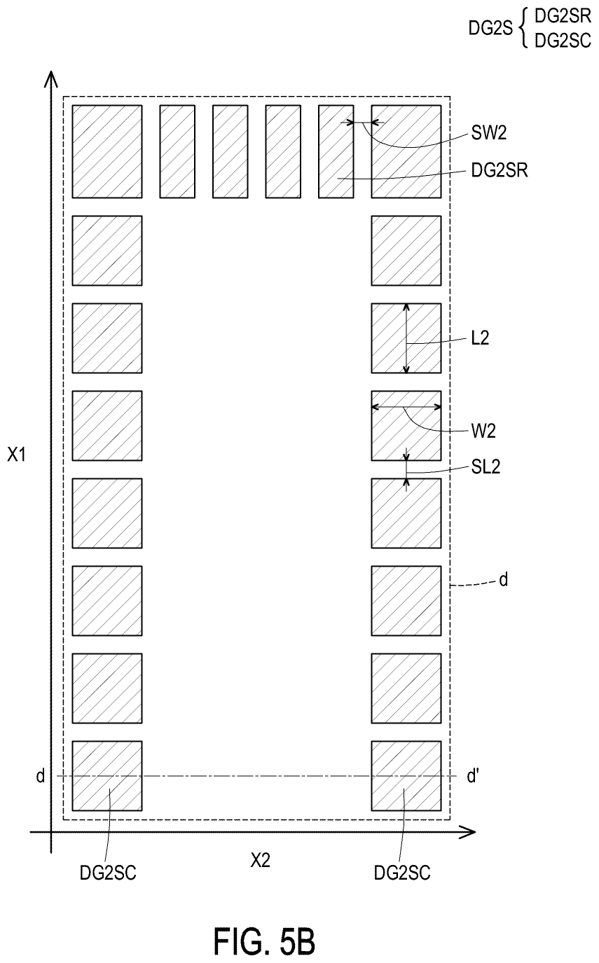

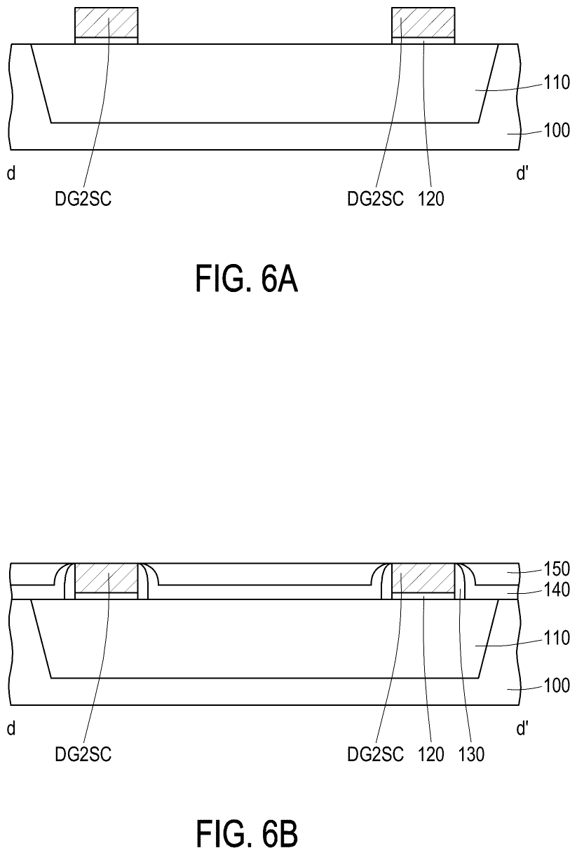

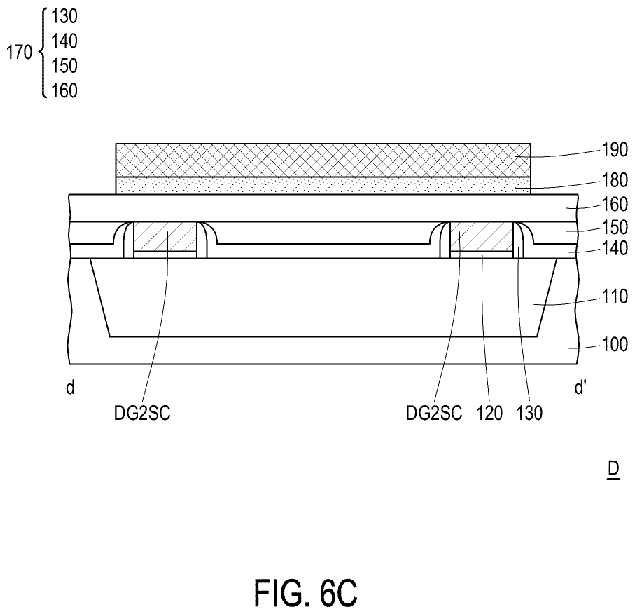

According to another embodiment provided by the disclosure, please refer to FIG. 5A, FIG. 5B and FIG. 6A to FIG. 6C at the same time. FIG. 5A is a layout schematic view of a semiconductor device D according to another embodiment of the disclosure. FIG. 5B is a partial enlarged view of a dotted box d of the semiconductor device D in FIG. 5A. FIG. 6A to FIG. 6C are cross-sectional schematic views of a method of forming the semiconductor device D viewed along section line dd′ of FIG. 5A and FIG. 5B.

In addition, since the embodiment and the foregoing embodiment have corresponding inventive concepts, the same materials used for the same elements will not be described again.

First, as shown in FIG. 5A and FIG. 6A, the semiconductor device D and the method of forming the same according to the embodiment include: a semiconductor substrate 100 is provided; an isolation region 110 is embedded in the semiconductor substrate 100; a dummy metal gate DG2 is formed between diffusion regions DIFF on the isolation region 110 that the dummy metal gate DG2 is divided into multiple independent discrete segments DG2S along a first axis X1 of the dummy metal gate DG2 and a second axis X2 of the dummy metal gate DG2, and the first axis X1 and the second axis X2 are perpendicular to each other, as shown in FIG. 5A, FIG. 5B and FIG. 6A.

The foregoing isolation region 110 may include various isolation components, such as a shallow trench isolation.

The semiconductor device D further includes a gate oxide layer 120 between the isolation region 110 and the dummy metal gate DG2. As shown in FIG. 6A, the gate oxide layer 120 is between the isolation region 110 and multiple square independent discrete segments DG2SC.

The foregoing dummy metal gate DG2 is a hollow rectangle, as shown in FIG. 5A. In the hollow rectangular dummy metal gate DG2, every independent discrete segment DG2S divided by the first axis X1 of the dummy metal gate DG2 and the second axis X2 of the dummy metal gate DG2 may be chosen as needed to be divided into appearances such as same dimensions and same shapes, different dimensions and same shapes, same dimensions and different shapes, or different dimensions and different shapes. Each of the multiple independent discrete segments DG2S may be a rectangle, such as strip, square; alternatively, each of the multiple independent discrete segments DG2S may be non-rectangular, for example, polygons such as circle, triangle, trapezoid, pentagon and hexagon, or various layout shapes generated by any optical operation, but it is not limited thereto.

For example, as shown in FIG. 5A and FIG. 5B, each of the multiple independent discrete segments DG2S is a rectangle, and squares and scalene rectangles of different dimensions are included. More specifically, as shown in FIG. 5A and FIG. 5B, the multiple independent discrete segments DG2S include the multiple square independent discrete segments DG2SC adjacent to the diffusion regions DIFF, and multiple rectangular independent discrete segments DG2SR of the multiple independent discrete segments DG2S not adjacent to the upper and lower parts of the diffusion regions DIFF, but the actual application is not limited thereto. Various suitable cutting types may be designed as needed.

Based on the above, taking the segments DG2S that include the multiple square independent discrete segments DG2SC adjacent to the diffusion regions DIFF as an example, as shown in FIG. 5B, every square independent discrete segment DG2SC has a length L2 along the first axis X1, and every square independent discrete segment DG2SC has a width W2 along the second axis X2. The length L2 and the width W2 are equal. In addition, every square independent discrete segment DG2SC has a pitch SL2 along the first axis X1, and every rectangular independent discrete segment DG2SR has a pitch SW2 along the second axis X2.

Since the hollow rectangular dummy metal gate DG2 shown in FIG. 5A has been hollowed out in the middle, the area has become much smaller compared to the area of the original large-area bulk dummy metal gate DG shown in FIG. 1A. Therefore, the probability of metal precipitation ME has become smaller. In addition, according to the layout of the semiconductor device C similar to the foregoing embodiment, the multiple independent discrete segments DG2S that include the multiple rectangular independent discrete segments DG2SR and the multiple square independent discrete segments DG2SC divided along the first axis X1 of the dummy metal gate DG2 and the second axis X2 of the dummy metal gate DG2 shown in FIG. 5A, with the presence of the pitch SL2 and the pitch SW2, the area of every rectangular independent discrete segment DG2SR and the area of every square independent discrete segment DG2SC have become much smaller than the area of the original bulk dummy metal gate DG. Therefore, the probability of metal precipitation from the multiple rectangular independent discrete segments DG2SR and the multiple square independent discrete segments DG2SC is also relatively much smaller. In addition, there is still support from the dummy metal gate DG2 in the region that may also avoid the occurrence of a phenomenon of dishing after CMP; that is to say, based on the layout design of the special dummy metal gate of the disclosure, a problem of metal precipitation of the dummy metal gate and a phenomenon of dishing after CMP may be solved at the same time.

The dimension of each of the foregoing independent discrete segments DG2S may be about 0.01 microns to about 10 microns, more preferably about 0.05 microns to about 5 microns, and most preferably about 0.1 microns to about 3 microns. The dimension refers to values such as lengths, widths, and diameters. That is to say, as shown in FIG. 5B, since the length L2 and the width W2 of every square independent discrete segment DG2SC are equal, the length L2 and the width W2 may be about 0.01 microns to about 10 microns, more preferably about 0.05 microns to about 5 microns, and most preferably about 0.1 microns to about 3 microns. If the dimension of every independent discrete segment DG2S is too small, it may cause a burden on processes, such as photolithography, and there may still be a phenomenon of dishing after CMP due to insufficient bearing capacity. However, if the dimension of every independent discrete segment DG2S is too large, the metal of the dummy metal gate DG2 is still very likely to be precipitated.

The dimension range of every independent discrete segment DG2S taught above is sufficient to be applied in a high-voltage device, a medium-voltage device, a low-voltage device or a combination thereof, so the disclosure is a disclosure that can be widely applied.

In addition, the pitch SL2 and the pitch SW2 may be about 0.329 microns to about 0.116 microns, more preferably about 0.154 microns to about 0.116 microns, and most preferably about 0.120 microns to about 0.116 microns.

Please refer to FIG. 6B and FIG. 6C. A dielectric layer 170 is formed to cover the dummy metal gate DG2. The dielectric layer 170 may include a sidewall 130, a contact etching stop layer 140, an interlayer dielectric layer 150, and an upper dielectric layer 160, but it is not limited thereto.

For example, the sidewalls 130 and the contact etching stop layer 140 may be conformally formed on the sidewalls of every rectangular independent discrete segment DG2SR and every square independent discrete segment DG2SC and on the semiconductor substrate 100 and the isolation region 110. Next, the interlayer dielectric layer 150 is formed on the contact etching stop layer 140. The side walls 130, the contact etching stop layer 140, the interlayer dielectric layer 150 on every rectangular independent discrete segment DG2SR and every square independent discrete segment DG2SC are removed by a global planarization method, such as CMP, to allow each of the multiple independent discrete segments DG2S to be coplanar. Since FIG. 6A to FIG. 6C are cross-sectional views of a method of forming the semiconductor device D along section line dd′ of FIG. 6A that do not include the multiple rectangular independent discrete segments DG2SR, only the formation of the multiple square independent discrete segments DG2SC is shown.

Please refer to FIG. 6C. Next, the upper dielectric layer 160 is formed on the multiple independent discrete segments DG2S and the interlayer dielectric layer 150. Then, a high resistance impedance layer 180 is formed on the dielectric layer 170, and a capping layer 190 is formed on the high resistance impedance layer 180.

By dividing the dummy metal gate into the multiple independent discrete segments, and even hollowing out the middle of the dummy metal gate, the entire area of the dummy metal gate is reduced. In addition, the area of every independent discrete segment that has been divided is significantly reduced compared to the area of the original large-area bulk dummy metal gate. Therefore, the probability of metal precipitation is also significantly reduced. In addition, since the dummy metal gate still exists in the region, a phenomenon of dishing after CMP may also be prevented.

That is to say, based on the layout design of the special dummy metal gate of the disclosure, a problem of metal precipitation of the dummy metal gate and a phenomenon of dishing after CMP may be solved at the same time.

In addition, the semiconductor device and the method of forming the same taught in the disclosure may be applied in a high-voltage device, a medium-voltage device, a low-voltage device or a combination thereof, so it is a disclosure that can be widely applied.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A semiconductor device, comprising:
a semiconductor substrate;
an isolation region, located in the semiconductor substrate;
a dummy metal gate, located on the isolation region, wherein the dummy metal gate is divided into a plurality of independent discrete segments along a first axis of the dummy metal gate and a second axis of the dummy metal gate, wherein the first axis and the second axis are perpendicular to each other;
a dielectric layer, covering the dummy metal gate;
a high resistance impedance layer, located on the dielectric layer; and
a capping layer, located on the high resistance impedance layer.

2. The semiconductor device according to claim 1, wherein the semiconductor device is a high-voltage device, a medium-voltage device, a low-voltage device or a combination thereof.

3. The semiconductor device according to claim 1, wherein the isolation region comprises a shallow trench isolation.

4. The semiconductor device according to claim 1, further comprising a gate oxide layer between the isolation region and the dummy metal gate.

5. The semiconductor device according to claim 1, wherein the dummy metal gate is a rectangle.

6. The semiconductor device according to claim 1, wherein the dummy metal gate is a hollow rectangle.

7. The semiconductor device according to claim 1, wherein each of the plurality of independent discrete segments is coplanar.

8. The semiconductor device according to claim 1, wherein each of the plurality of independent discrete segments is a rectangle.

9. The semiconductor device according to claim 1, wherein each of the plurality of independent discrete segments is non-rectangular.

10. The semiconductor device according to claim 1, wherein dimensions of the plurality of independent discrete segments are 0.01 microns to 10 microns.

11. A method of forming a semiconductor device, comprising:
providing a semiconductor substrate;
embedding an isolation region in the semiconductor substrate;
forming a dummy metal gate on the isolation region, wherein the dummy metal gate is divided into a plurality of independent discrete segments along a first axis of the dummy metal gate and a second axis of the dummy metal gate, wherein the first axis and the second axis are perpendicular to each other;
forming a dielectric layer to cover the dummy metal gate;
forming a high resistance impedance layer on the dielectric layer; and
forming a capping layer on the high resistance impedance layer.

12. The method of forming a semiconductor device according to claim 11, wherein the semiconductor device is a high-voltage device, a medium-voltage device, a low-voltage device or a combination thereof.

13. The method of forming a semiconductor device according to claim 11, wherein the isolation region comprises a shallow trench isolation.

14. The method of forming a semiconductor device according to claim 11, further comprising a gate oxide layer between the isolation region and the dummy metal gate.

15. The method of forming a semiconductor device according to claim 11, wherein the dummy metal gate is a rectangle.

16. The method of forming a semiconductor device according to claim 11, wherein the dummy metal gate is a hollow rectangle.

17. The method of forming a semiconductor device according to claim 11, wherein each of the plurality of independent discrete segments is coplanar.

18. The method of forming a semiconductor device according to claim 11, wherein each of the plurality of independent discrete segments is a rectangle.

19. The method of forming a semiconductor device according to claim 11, wherein each of the plurality of independent discrete segments is non-rectangular.

20. The method for forming a semiconductor device according to claim 11, wherein dimensions of the plurality of independent discrete segments are 0.01 microns to 10 microns.
